(19) United States
(12) Patent Application Publication
(10) Pub. No.: US 2026/0349897 A1
(43) Pub. Date: Nov. 5, 2026

(54) SYSTEMS AND METHODS FOR SYNCHRONIZED TRACING OF EVENTS ON CENTRAL PROCESSING UNITS AND DIGITAL LOGIC DEVICES

(71) Applicant: Ciena Corporation, Hanover, MD (US)

(72) Inventors: François Tétreault, Ottawa (CA); James Hunter Keith Sanderson, Ottawa (CA); David James Evans, Ottawa (CA); John Andrew Earl, Ottawa (CA); Daniel Claude Perras, Ottawa (CA)

(21) Appl. No.: 19/195,802

(22) Filed: May 1, 2025

(51) Int. Cl. G06F 11/30; H03L 7/18

(52) U.S. Cl. CPC G06F 11/3072; G06F 11/3024; H03L 7/18

(57) ABSTRACT

A system and method for applying a software tracing methodology in a digital logic device domain, for use in the digital logic device domain or a combination of a software domain and the digital logic device domain. Event traces received from software and hardware are analyzed by receiving an event trace from a central processing unit (CPU) running a software application, receiving an event trace from a digital logic device associated with the CPU and software application, and synchronizing a timestamp associated with the event trace received from the CPU with a timestamp associated with the event trace received from the digital logic device by applying a determined offset to one of the timestamp associated with the event trace received from the CPU and the timestamp associated with the event trace received from the digital logic device. The offset is applied to the timestamps inline in real-time or via post-processing.

### TECHNICAL FIELD

The present disclosure relates generally to the networking and telecommunications fields. More particularly, the present disclosure relates to systems and methods for the synchronized tracing of events on central processing units (CPUs) and digital logic devices, including systems and methods for timestamp synchronization between traces collected on CPUs and digital logic devices. Further, the present disclosure relates to the application of a software tracing methodology in a digital logic device domain, for use in the digital logic device domain or a combination of a software domain and the digital logic device domain.

### BACKGROUND

Conventionally, there are inadequate tracing solutions that span both the software (CPU) and digital logic device (field-programmable gate array (FPGA), application-specific integrated circuit (ASIC), programmable logic device (PLD), etc.) domains, allowing the interaction of these domains to be explored. Multiple tracing solutions exist on the software side. Similarly, multiple tracing solutions exist on the digital logic device side.

Conventionally, software tracing solutions support the kernel, device drivers, and user-space applications. These solutions accommodate containers, virtualization, graphics processing units (GPUs), and various processor architectures. However, the solutions lack the ability to trace within other devices, such as FPGAs, ASICs, and PLDs.

Conventionally, as illustrated in FIG. 1, bugs are separately investigated on a digital logic device 102 of a device under test 100 during interaction with a CPU 104 of the device under test 100. This approach involves collecting a software trace on the CPU 104 using a software tracing solution 106 while simultaneously monitoring the software for the manifestation of the bug. Additionally, an interface analyzer 108 is connected to an interface 110 between the CPU 104 and an ASIC, for example. The objective of the approach is to capture and record both the software trace and the interface analyzer data simultaneously, requiring synchronization between the two. Once the interface analyzer data is available, an ASIC expert emulates the scenario in the ASIC and investigates the root cause of the problem. While reasonably effective, the approach is tedious and involves several steps: connecting the interface analyzer 108 to the device under test 100, reproducing the problem on the device under test 100, developing custom software to detect the problem and halt the trace, emulating the ASIC logic based on the data collected by the interface analyzer 108, identifying the root cause of the problem, and proposing a solution.

None of the conventional tracing solutions for software or digital logic devices effectively capture both software and digital logic device aspects simultaneously. While it is not impossible to conceive of utilizing both software and hardware solutions concurrently, this requires tremendous effort to implement. Typically, in order to collect data from both the software and hardware sides, the problem must be reproduced on the device under test 100 using different solutions. Further, before the root cause of the problem and solution can be identified, it is necessary to emulate the problem for investigating the digital logic device 102. This step adds complexity and further effort to the process. Additionally, it may not be feasible or possible to reproduce the same conditions in a simulation or emulation environment.

In addition, in a tracing solution that spans both the software and digital logic device domains, the problem of synchronizing timestamps inline or via post-processing is new and has not been addressed. This problem is exacerbated by the diverse types of clock sources associated with CPUs and FPGAs, ASICs, or PLDs.

In other contexts, solutions have been implemented to capture and display the behavior of signals as a given design changes over time, offering insight into how the various signals interact with each other. The display is in the form of waveforms or a timing diagram. Likewise, a phase-locked loop (PLL) is a common mechanism used to synchronize a clock to a reference clock. The purpose of the PLL is to continually adjust the phase and frequency of the clock to the reference clock. Further, solutions have been studied for synchronizing clocks between traces collected on different computers with different clocks. These solutions provide insight, but do not address synchronizing timestamps inline or via post-processing in a tracing solution that spans both the software and digital logic device domains.

The present background is provided as illustrative environmental context only. It will be readily apparent to those of ordinary skill in the art that the concepts and principles of the present disclosure may be implemented in other environmental contexts and applications equally, without limitation.

### BRIEF SUMMARY OF THE INVENTION

The present disclosure provides a tracing solution that spans both the software (CPU) and digital logic device (FPGA, ASIC, PLD, etc.) or hardware domains, allowing the interaction of these domains to be explored. The present disclosure also provides a solution for synchronizing timestamps inline or via post-processing, accommodating the diverse types of clock sources associated with CPUs and FPGAs, ASICs, or PLDs.

In some embodiments, a method for analyzing event traces received from software and hardware includes receiving an event trace from a central processing unit (CPU) running a software application, receiving an event trace from a digital logic device associated with the CPU and software application, and synchronizing a timestamp associated with the event trace received from the CPU with a timestamp associated with the event trace received from the digital logic device by applying a determined offset to one of the timestamp associated with the event trace received from the CPU and the timestamp associated with the event trace received from the digital logic device. In some embodiments, the digital logic device is one of a field-programmable gate array (FPGA), an application-specific integrated circuit (ASIC), and a programmable logic device (PLD). In some embodiments, the offset is applied to the one of the timestamp associated with the event trace received from the CPU and the timestamp associated with the event trace received from the digital logic device inline in real-time as the event trace is received from the CPU and the event trace is received from the digital logic device. The offset is determined by, for a leader of the CPU and the digital logic device and a follower of the CPU and the digital logic device, generating by the leader a periodic event Xn and timestamping the event Xn as T1 in a trace of the leader, detecting the event Xn generated by the leader at the follower and timestamping the event Xn as T2 in a trace of the follower, generating by the follower a response event Yn and timestamping the event Yn as T3 in a trace of the follower, detecting the event Yn generated by the follower at the leader and timestamping the event Yn as T4 in a trace of the leader, and calculating the offset as: (T1−T2−T3+T4)/2. The offset is applied to the one of the timestamp associated with the event trace received from the CPU and the timestamp associated with the event trace received from the digital logic device by filtering the offset and adjusting one or more of a phase and a frequency of a clock of one of the CPU and the digital logic device. The one or more of the phase and the frequency of the clock of the one of the CPU and the digital logic device is adjusted by one of adjusting the phase-locked loop (PLL)/digital PLL (DPLL) that is synthesizing the clock and adjusting a time interval used to increment the clock. In some embodiments, the offset is applied to the one of the timestamp associated with the event trace received from the CPU and the timestamp associated with the event trace received from the digital logic device via post-processing after the event trace is received from the CPU and the event trace is received from the digital logic device. The timestamp associated with the event trace received from the CPU is synchronized with the timestamp associated with the event trace received from the digital logic device by examining event trace files received from the CPU and event trace files received from the digital logic device and identifying common events that occurred on the CPU and the digital logic device, where common events occurring in one direction are identified to correct a frequency of the timestamps and common events occurring in both directions are identified to correct a time of the timestamps, calculating delays of successive events that occur at one of the CPU and the digital logic device and then another of the CPU and the digital logic device, filtering the calculated delays, calculating a time correction sequence, and applying the time correction sequence to the one of the timestamp associated with the event trace received from the CPU and the timestamp associated with the event trace received from the digital logic device as the offset. The time correction sequence is calculated using a digital phase-locked loop (DPLL) process by selecting a leader trace file and a follower trace file with an initial time correction sequence set to zero; using a frequency/phase detector to calculate a frequency/phase error between timestamps from the leader trace file and the follower trace file; if only correcting for frequency, calculating a difference between successive timestamps for the leader trace file and the follower trace file and then calculating a difference in time intervals for the leader trace file and the follower trace file; if correcting for phase,
for an event that is initiated in the leader trace file,
letting T1 be a timestamp of the event in the leader trace file, and
letting T2 be a timestamp of the event in the follower trace file,
for an event that is initiated on in the follower trace file,
letting T3 be a timestamp of the event in the follower trace file, and
letting T4 be a timestamp of the event in the leader trace file,
where the time error is calculated as error=(T1−T2−T3+T4)/2; and
applying the calculated error as the time correction sequence.

In some embodiments, a non-transitory computer-readable medium including instructions stored in a memory and executed by a processor for carrying out steps of a method for analyzing event traces received from software and hardware, the method including receiving an event trace from a central processing unit (CPU) running a software application, receiving an event trace from a digital logic device associated with the CPU and software application, and synchronizing a timestamp associated with the event trace received from the CPU with a timestamp associated with the event trace received from the digital logic device by applying a determined offset to one of the timestamp associated with the event trace received from the CPU and the timestamp associated with the event trace received from the digital logic device. The offset is applied to the one of the timestamp associated with the event trace received from the CPU and the timestamp associated with the event trace received from the digital logic device inline in real-time as the event trace is received from the CPU and the event trace is received from the digital logic device or via post-processing after the event trace is received from the CPU and the event trace is received from the digital logic device.

In some embodiments, a system for analyzing event traces received from software and hardware includes a trace analyzer stored in memory and executed by a processor to receive an event trace from a central processing unit (CPU) running a software application, receive an event trace from a digital logic device associated with the CPU and software application, and synchronize a timestamp associated with the event trace received from the CPU with a timestamp associated with the event trace received from the digital logic device by applying a determined offset to one of the timestamp associated with the event trace received from the CPU and the timestamp associated with the event trace received from the digital logic device. In some embodiments, the digital logic device is one of a field-programmable gate array (FPGA)an application-specific integrated circuit (ASIC), and a programmable logic device (PLD). In some embodiments, the offset is applied to the one of the timestamp associated with the event trace received from the CPU and the timestamp associated with the event trace received from the digital logic device inline in real-time as the event trace is received from the CPU and the event trace is received from the digital logic device. The offset is determined by, for a leader of the CPU and the digital logic device and a follower of the CPU and the digital logic device, generating by the leader a periodic event Xn and timestamping the event Xn as T1 in a trace of the leader, detecting the event Xn generated by the leader at the follower and timestamping the event Xn as T2 in a trace of the follower, generating by the follower a response event Yn and timestamping the event Yn as T3 in a trace of the follower, detecting the event Yn generated by the follower at the leader and timestamping the event Yn as T4 in a trace of the leader, and calculating the offset as: (T1−T2−T3+T4)/2. The offset is applied to the one of the timestamp associated with the event trace received from the CPU and the timestamp associated with the event trace received from the digital logic device by filtering the offset and adjusting one or more of a phase and a frequency of a clock of one of the CPU and the digital logic device. The one or more of the phase and the frequency of the clock of the one of the CPU and the digital logic device is adjusted by one of adjusting the phase-locked loop (PLL)/digital PLL (DPLL) that is synthesizing the clock and adjusting a time interval used to increment the clock. In some embodiments, the offset is applied to the one of the timestamp associated with the event trace received from the CPU and the timestamp associated with the event trace received from the digital logic device via post-processing after the event trace is received from the CPU and the event trace is received from the digital logic device. The timestamp associated with the event trace received from the CPU is synchronized with the timestamp associated with the event trace received from the digital logic device by examining event trace files received from the CPU and event trace files received from the digital logic device and identifying common events that occurred on the CPU and the digital logic device, where common events occurring in one direction are identified to correct a frequency of the timestamps and common events occurring in both directions are identified to correct a time of the timestamps, calculating delays of successive events that occur at one of the CPU and the digital logic device and then another of the CPU and the digital logic device, filtering the calculated delays, calculating a time correction sequence, and applying the time correction sequence to the one of the timestamp associated with the event trace received from the CPU and the timestamp associated with the event trace received from the digital logic device as the offset. The time correction sequence is calculated using a digital phase-locked loop (DPLL) process by selecting a leader trace file and a follower trace file with an initial time correction sequence set to zero; using a frequency/phase detector to calculate a frequency/phase error between timestamps from the leader trace file and the follower trace file; if only correcting for frequency, calculating a difference between successive timestamps for the leader trace file and the follower trace file and then calculating a difference in time intervals for the leader trace file and the follower trace file; if correcting for phase,
for an event that is initiated in the leader trace file,
letting T1 be a timestamp of the event in the leader trace file, and
letting T2 be a timestamp of the event in the follower trace file,
for an event that is initiated on in the follower trace file,
letting T3 be a timestamp of the event in the follower trace file, and
letting T4 be a timestamp of the event in the leader trace file,
where the time error is calculated as error=(T1−T2−T3+T4)/2; and
applying the calculated error as the time correction sequence.

It will be readily apparent to those of ordinary skill in the art that features and aspects of the described embodiments may be included, omitted, or combined as desired in a given application, without limitation.

### BRIEF DESCRIPTION OF THE DRAWINGS

The present disclosure is illustrated and described with reference to the various drawings, in which like reference numbers are used to denote like system components/method steps, as appropriate.

FIG. 1 is a schematic diagram illustrating a conventional solution for collecting traces for both the software (CPU) and digital logic device (FPGA, ASIC, PLD, etc.) or hardware domains.

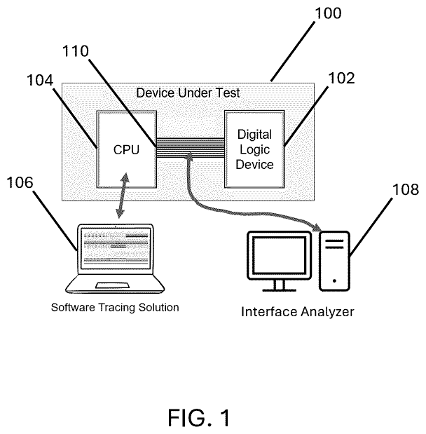

FIG. 2 is a schematic illustrating the software tracing ecosystem of the present disclosure.

FIG. 3 is a schematic illustrating the digital logic device or hardware tracing ecosystem of the present disclosure.

FIG. 4 is a schematic illustrating one embodiment of the combined software and digital logic device or hardware tracing system and method of the present disclosure.

FIG. 5 is a flowchart illustrating one embodiment of the inline (real-time) timestamp synchronization method of the present disclosure, where, for each iteration of periodic events X(n) and Y(n) generated by two devices A and B, four timestamps (T1, T2, T3, and T4) are generated.

FIG. 6 is a flowchart illustrating another embodiment of the inline (real-time) timestamp synchronization method of the present disclosure, where the timestamp synchronization process is modeled as a digital PLL (DPLL).

FIG. 7 is a flowchart illustrating one embodiment of the post-processing timestamp synchronization method of the present disclosure.

FIG. 8 is a flowchart illustrating another embodiment of the post-processing timestamp synchronization method of the present disclosure, where the timestamp synchronization process is modeled as a DPLL.

It will be readily apparent to those of ordinary skill in the art that features and aspects of the illustrated embodiments may be included, omitted, or combined as desired in a given application, without limitation.

### DETAILED DESCRIPTION

Again, the present disclosure provides a tracing solution that spans both the software (CPU) and digital logic device (FPGA, ASIC, PLD, etc.) or hardware domains, allowing the interaction of these domains to be explored. The present disclosure also provides a solution for synchronizing timestamps inline or via post-processing, accommodating the diverse types of clock sources associated with CPUs and FPGAs, ASICs, or PLDs.

Extending software tracing to digital logic devices provides several benefits.

The first benefit is observability. Tracing provides comprehensive insight into the internal workings of a system. By extending tracing to digital logic devices, such as FPGAs, ASICs, and PLDs, understanding of the overall operation of the system can be further enhanced. Without tracing, digital logic devices, such as FPGAs, ASICs, and PLDs, essentially function as “black boxes,” making it difficult to understand their internal processes. However, with the implementation of tracing, one not only observes the activities within the FPGAs, ASICs, and PLDs, but also gains insights into how the software interacts with these digital logic devices. This level of observability is crucial for diagnosing issues, optimizing performance, and improving the overall functionality of the system.

The second benefit is debugging. Without tracing on a digital logic device, the information that can be collected for debugging is limited to software tracing and data captured by an interface analyzer (e.g., a PCIe protocol analyzer or the like). An interface analyzer can decode and display the communication happening on a bus, providing visibility into the interactions between different devices connected to the bus. However, it does not provide insight into what is happening inside the device. In the absence of FPGA, ASIC, or PLD tracing, the next step typically involves simulating and investigating the problem using an ASIC, FPGA, or PLD simulator. This can be a tedious and time-consuming process, as it requires replicating the conditions under which the issue occurred to identify the cause. However, with FPGA, ASIC, and PLD tracing, these steps can be significantly streamlined. The tracing captures data as the issue occurs, providing a real-time record of the events leading up to the problem. This means that designers can bypass the simulation stage and focus directly on analyzing the trace data to identify and fix the issue. This makes the debugging process more efficient and accurate, saving valuable time and resources.

The third benefit is performance improvement. Occasionally, a transaction may take longer than expected to process within an FPGA, ASIC, or PLD. With the data provided by tracing, the conditions leading to this performance issue can be analyzed. This allows for the identification and mitigation of any bottlenecks or inefficiencies, ensuring that the system meets performance expectations. This process, as with debugging, saves valuable time and resources by pinpointing the exact area of concern, thereby reducing the time spent on guesswork or extensive testing.

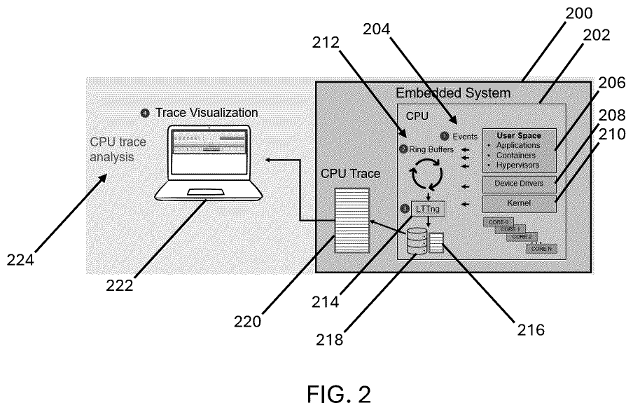

FIG. 2 is a schematic illustrating the software tracing ecosystem (system and method) of the present disclosure. At (1), events are collected as the software 202 of the embedded system 200 executes. Each event 204 associated with the user space 206 (applications, containers, and hypervisors), device drivers 208, and the kernel 210 contains a timestamp, an event identification (ID), and associated data. At (2), the events 204 are encoded in binary format and stored in random access memory (RAM) ring buffers 212. At (3), a daemon 214 (LTTng for Linux or the like) collects the events 204 from the ring buffers 212 and transfers them to a file 216 on the file system 218. Tracing is stropped once the data of interest is collected. At (4), the CPU trace 220 is transferred to a trace visualization workstation 222 where the software trace is analyzed using a software trace analyzer 224 provided as instructions stored in a memory (non-transitory computer-readable medium) and executed by a processor of the trace visualization workstation 222. Available solutions involve: graphical analysis (the trace can be loaded into a graphical visualizing tool where a comprehensive list of automated analyses are available), analysis scripts (the trace can be automatically analyzed by a script), machine learning (ML) and artificial intelligence (AI) (the trace can be automatically analyzed by ML and AI), and manual analysis (the trace can be decoded to a human-readable format).

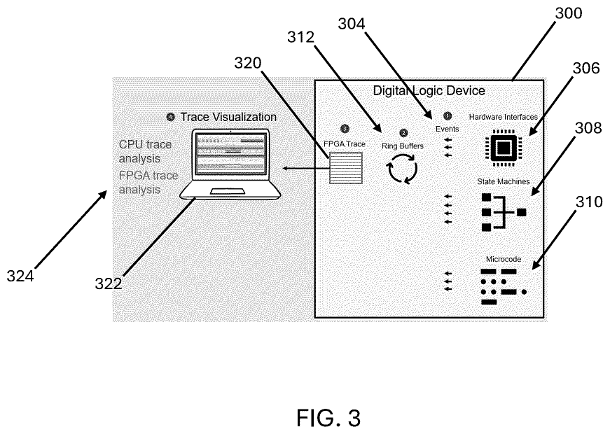

FIG. 3 is a schematic illustrating the digital logic device or hardware tracing ecosystem (system and method) of the present disclosure. The digital logic devices 300 are set up to collect traces in a way that is similar to software. At (1), events 304 and associated timestamps are captured when specific triggers are activated at hardware interfaces 306, during state machine transitions 308, or through the execution of microcode 310 within the digital logic device 300. At (2), these events 304 are stored in ring buffers 312. Each event 304 is assigned a unique event ID and a value which increments by one each time is generated (local timestamp and associated data). Events 304 can be overwritten or lost by design, to avoid impacting the normal operation of the system when the tracing system is overwhelmed. At (3), tracing can be stopped either manually or upon an automatic trigger, at which point a snapshot is available in the internal RAM (i.e., the tracing of individual events can be enabled or disabled, as opposed to all tracing being enabled or disabled). At (4), the hardware (FPGA, ASIC, or PLD) traces 320 collected for the digital logic device 300 can be analyzed side-by-side with the software traces 220 at the trace visualization workstation 322 (the trace visualization workstation 222) where the hardware traces 320 are analyzed using a hardware trace analyzer 324 (the software trace analyzer 224) also provided as instructions stored in a memory (non-transitory computer-readable medium) and executed by a processor of the trace visualization workstation 322. Again, available solutions involve: graphical analysis (the traces can be loaded into a graphical visualizing tool where a comprehensive list of automated analyses are available), analysis scripts (the traces can be automatically analyzed by a script), ML and AI (the traces can be automatically analyzed by ML and AI), and manual analysis (the traces can be decoded to a human-readable format).

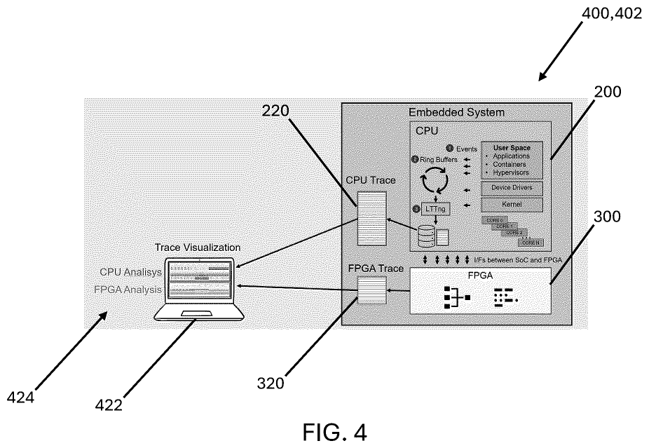

FIG. 4 is a schematic illustrating one embodiment of the combined software and digital logic device or hardware tracing system 400 and method 402 of the present disclosure. The system 400 combines the above software tracing ecosystem and the above hardware tracing ecosystem into a combined ecosystem with the traces 220, 320 analyzed at a common trace visualization workstation 422 using a common trace analyzer 424. By having the same tracing format and approach for trace collection and analysis, the software traces 220 can be collected side-by-side with the hardware traces 320 collected on the digital logic device 300.

The system and method of the present disclosure eliminate the need for a specific device under test and the utilization of separate solutions for software and hardware. Further, the system and method eliminate the necessity to emulate the problem based on the collected data. As a result, the system and method offer a more practical, flexible, and convenient solution with a significantly faster turnaround time for identifying the root cause and providing a solution. This is valuable in various scenarios, including problem investigation in the field, laboratory, during development, or during FPGA, ASIC, or PLD regression. Another significant benefit is that the system and method empower designers to effectively investigate complex issues.

As alluded to above, the hurdles associated with applying a software tracing ecosystem to a hardware tracing ecosystem include trace formatting (which is typically bigger for a CPU), timestamp synchronization, and the fact that the CPU has access to all data, while a FPGA, ASIC, or PLD typically does not. The present disclosure address this timestamp synchronization issue, in both inline (real-time) and post-processing applications.

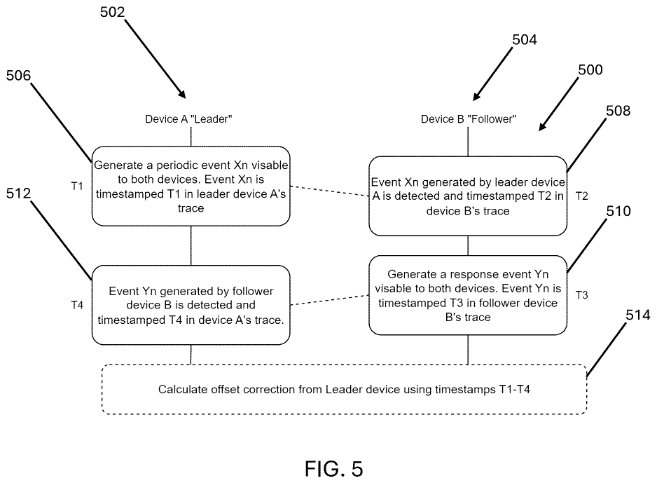

Referring to FIG. 5, the inline (real-time) timestamp synchronization method 500 of the present disclosure correlates events that are captured and timestamped by device A 502 and device B 504 (such as a CPU associated with software and a FPGA, ASIC, or PLD associated with a digital logic device or hardware) that use different reference clocks (i.e., reference clocks that are not in phase or that run at different frequencies). In general, in software development and debugging, tracing refers to the process of capturing and recording information about the execution of a program. Tracing captures and timestamps events that occur during runtime of a program, including function calls, variable values, and control flows. Tracing is often used to diagnose issues, understand program behavior, and optimize performance.

Modern computer systems are comprised of several integrated circuits that performs the various functions of the system. Many of these devices (CPUs, FPGAs, ASICs, PLDs, etc.) are capable of recording traces. However, it is common for these devices to use clocks that are not synchronized. Therefore, it is difficult to correlate events in traces recorded by these different devices. The timestamp synchronization method 500 of the present disclosure enables two or more devices to establish a common time base that allows the subsequent trace captures from multiple devices to be correlated, with or without post-processing.

As shown in FIG. 5, for device A 502 and device B 504, for each iteration of periodic events X(n) and Y(n) generated, four timestamps (T1, T2, T3, and T4) are generated. First, at step 506, leader device A 502 generates a periodic event Xn visible to both device A 502 and device B 504, and event Xn is timestamped T1 in the trace of device A 502. Second, at step 508, event Xn generated by device A 502 is detected and timestamped T2 in the trace of follower device B 504. Third, at step 510, device B 504 generates a response event Yn visible to both device A 502 and device B 504, and event Yn is timestamped T3 in the trace of device B 504. Fourth, at step 512, event Yn generated by device B 504 is detected and timestamped T4 in the trace of device A 502. Finally, as described in greater detail below, the timestamp offset correction from leader device A 502 is calculated for follower device B 504 using timestamps T1, T2, T3, and T4. Subsequently, this timestamp offset correction is applied between device A 502 and device B before tracing is performed, thereby providing a real-time timestamp synchronization between the devices that may be recalculated and adjusted over time, if desired.

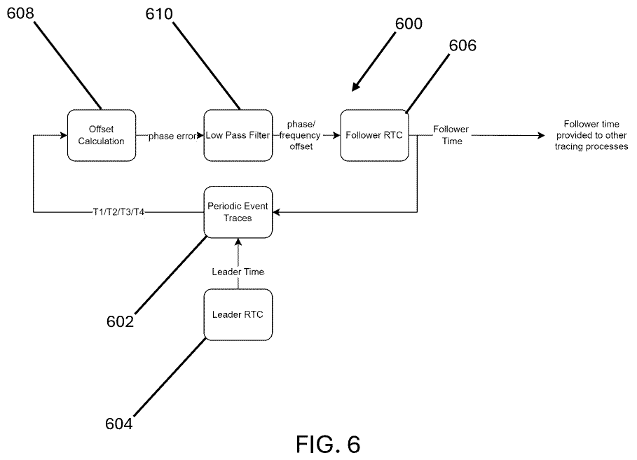

The method 600 of FIG. 6 models the inline (real-time) process as a DPLL. Periodic events 602 are generated and traced by both the leader and follower devices 604, 606 to generate the four timestamps, T1, T2, T3, and T4, as described above. The offset calculation 608 (or phase/frequency detector) calculates the phase error as: phase_error=(T1−T2−T3+T4)/2. Subsequently, a low pass filter 610 filters the calculated phase error, and the filtered phase error is used to offset the phase/frequency of the follower device 606. As adjustments are made to the clock of the follower device 606, periodic events 602 continue to be generated and traced to produce new timestamps. This creates a feedback loop. The clock of the follower device 606 is provided to other tracing process for use, synchronized with the clock of the leader device 604.

Depending on the implementation of the clock of the follower device 606, there are multiple potential methods for updating the phase/frequency of the clock depending on the capabilities of the hardware Time offsets can be applied directly to the clock to cause a phase adjustment to the clock. If the hardware allows, the phase/frequency of the physical clock being used can be adjusted using the PLL/DPLL that is synthesizing the clock. If the phase/frequency of the physical clock being used cannot be adjusted directly, the time interval used to increment the clock can be adjusted instead.

In essence, the methods 500, 600 of the present disclosure establish causality, and the timestamp synchronization is based on the type of follower. Timestamp synchronization may be performed slowly over multiple passes to prevent the generation of excessive jitter.

Thus, the present disclosure provides observability into digital logic devices and their interaction with software running on a CPU, with inline synchronization between software and digital logic device events, where the FPGAs, ASICs, or PLDs use an independent clock from the CPU clock. Existing solutions for FPGA, ASIC, and PLD tracing typically employ a bottom-up approach, starting from the hardware level. In contrast, the approach taken by the present disclosure is top-down, originating from the software level. It is software-centric, rather than hardware-centric.

The solution of the present disclosure offers a completely different approach to debugging and improving performance bottlenecks on FPGAs, ASICs, and PLDs. By addressing the problem of timestamping events and synchronizing traces collected from both software and digital logic devices, it enables effective tracing in digital logic devices. This opens new possibilities for identifying and resolving issues, ultimately leading to enhanced performance and efficiency in FPGA, ASIC, and PLD systems.

Again, the present disclosure provides methods for correlating events that are captured and timestamped by devices that use different reference clocks. The process of tracing involves recording a small amount of data (a trace) about an event in a computer system for the purpose of debugging. The event trace, or small amount of data, is timestamped to allow a sequence of events to be pieced together. A tracepoint refers to a specific location in code or logic where one can capture an event when the corresponding logic is executed or triggered. The events, or event traces, are timestamped. A trace, in general, is a collection of events recorded between two points in time: the start and stop of the tracing process. Modern computer systems are comprised of several integrated circuits that perform the various functions of the system. Many of these devices (CPUs, FPGAs, ASICs, PLDs, etc.) are capable of recording traces. However, it is common for these devices to use clocks that are not synchronized. Therefore, it is difficult to correlate events in the traces recorded by these different devices. The present disclosure provides a method for correlating events in traces that are recorded by devices that use different clocks, via post-processing in the embodiment described below.

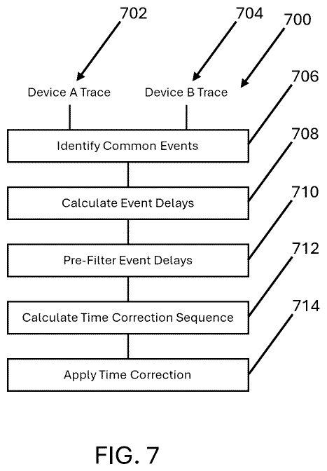

FIG. 7 is a flowchart illustrating one embodiment of the post-processing timestamp synchronization method 700 of the present disclosure. The first step 706 is to examine the trace files from device A 702 and device B 704 and identify events that occurred on each device 702, 704 that are related. For example, this could be a register access that is initiated by one device and executed on the other device. The idea is to find events that could be suitable for time recovery. These are events that take place on both devices 702, 704 and are timestamped in their trace files. To correct the frequency of the timestamps in the trace files, only events occurring in one direction (i.e., first on device A 702 then on device B 704, or first on device B 704 then on device A 702) are required. To correct the time offset of the timestamps in the trace files, events occurring in both directions are required.

The second step 708 is to calculate the delays of successive events that occur on one device then the other device. This forms a measurement of the delay between an event occurring on one device and the same event occurring on the other device.

The third step 710 is to pre-filter the calculated event delays. This is done to remove excessive delay variation. Delay variation may be a result of processing delays from when the event is timestamped on the source device until it is executed in hardware, or processing delays from when the event occurs at the destination device until when it is timestamped. The delay variation could also be a result of the interface technology that is used between the devices 702, 704. The pre-filtering process may need to be adjusted depending on the characteristics of the delay. For example, if the noise variation approximates a gamma distribution, a filter process that selects the floor delays may be appropriate. If the noise variation exhibits a gaussian distribution, no pre-filtering may be required. This pre-filtering step 710 can also apply to the inline (real-time) process of FIG. 6, prior to the calculation of the phase error.

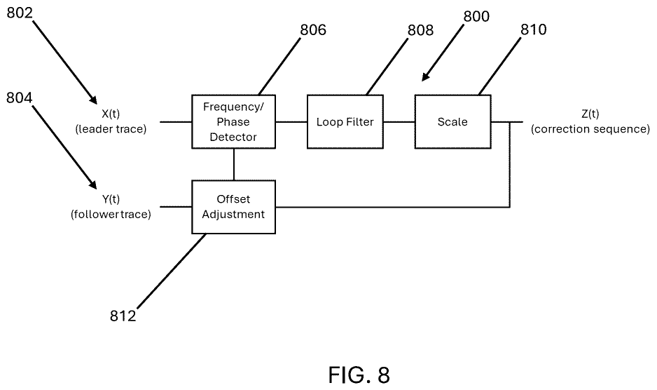

The fourth step 712 is to calculate a time correction sequence. This is achieved with a DPLL process 800, as illustrated in FIG. 8. One device trace is chosen to be the leader trace 802 and the other device trace is chosen to be the follower trace 804. The initial correction is set to zero. The timestamps from the follower trace 804 are adjusted by the correction before being fed into the DPLL process 800. The first step of the process 800 is the frequency/phase detector 806. The frequency/phase detector 806 calculates the error frequency/phase error between the timestamps from the two traces 802, 804. If only correcting for frequency, error can be calculated by first computing the difference between successive timestamps, or time interval, for each trace file, then calculating the difference in time intervals, or time interval error, between the two traces 802, 804. If correcting for phase, the error can be calculated as follows, considering two events; one that is initiated on the leader device and another that is initiated on the follower device:
For the event that is initiated on the leader device,
Let T1 be the timestamp of the event in the leader trace file, and
Let T2 be the timestamp of the event in the follower trace file,
For the event that is initiated on the follower device,
Let T3 be the timestamp of the event in the follower trace file, and
Let T4 be the timestamp of the event in the leader trace file,
The time error can be calculated as error=(T1−T2−T3+T4)/2.

After the frequency/phase error is calculated at the frequency/phase detector 806, the next step is to filter the error noise. This is typically done with a low-pass filter process 808. Lastly, the filtered error sequence is scaled via a scaling process 810. The output of this scaling process 810 is a correction sequence, Z(t). The output of each iteration of the process 800 is fed back to the input and applied to the follower sequence.

The fifth step 714 of FIG. 7 is to apply the time correction sequence to one of the trace files 802, 804 of FIG. 8 to correct the timestamps therein using the offset adjustment 812.

Again, the present disclosure provides observability into digital logic devices and their interaction with software running on a CPU, with inline synchronization between software and digital logic device events, where the FPGAs, ASICs, or PLDs use an independent clock from the CPU clock. Existing solutions for FPGA, ASIC, and PLD tracing typically employ a bottom-up approach, starting from the hardware level. In contrast, the approach taken by the present disclosure is top-down, originating from the software level. It is software-centric, rather than hardware-centric.

The solution of the present disclosure offers a completely different approach to debugging and improving performance bottlenecks on FPGAs, ASICs, and PLDs. By addressing the problem of timestamping events and synchronizing traces collected from both software and digital logic devices, it enables effective tracing in digital logic devices. This opens new possibilities for identifying and resolving issues, ultimately leading to enhanced performance and efficiency in FPGA, ASIC, and PLD systems.

Although the present disclosure is illustrated and described with reference to specific embodiments and examples, it will be readily apparent to those of ordinary skill in the art that other embodiments and examples may perform similar functions and/or achieve like results. All such equivalent embodiments and examples are within the spirit and scope of the present disclosure, are contemplated thereby, and are intended to be covered by the following non-limiting claims for all purposes, without limitation.

What is claimed is:

1. A method for analyzing event traces received from software and hardware, the method comprising
receiving an event trace from a central processing unit (CPU) running a software application,
receiving an event trace from a digital logic device associated with the CPU and software application, and
synchronizing a timestamp associated with the event trace received from the CPU with a timestamp associated with the event trace received from the digital logic device by applying a determined offset to one of the timestamp associated with the event trace received from the CPU and the timestamp associated with the event trace received from the digital logic device.

2. The method of claim 1, wherein the digital logic device is one of a field-programmable gate array (FPGA), an application-specific integrated circuit (ASIC), and a programmable logic device (PLD).

3. The method of claim 1, wherein the offset is applied to the one of the timestamp associated with the event trace received from the CPU and the timestamp associated with the event trace received from the digital logic device inline in real-time as the event trace is received from the CPU and the event trace is received from the digital logic device.

4. The method of claim 1, wherein the offset is determined by, for a leader of the CPU and the digital logic device and a follower of the CPU and the digital logic device, generating by the leader a periodic event Xn and timestamping the event Xn as T1 in a trace of the leader, detecting the event Xn generated by the leader at the follower and timestamping the event Xn as T2 in a trace of the follower, generating by the follower a response event Yn and timestamping the event Yn as T3 in a trace of the follower, detecting the event Yn generated by the follower at the leader and timestamping the event Yn as T4 in a trace of the leader, and calculating the offset as: (T1−T2−T3+T4)/2.

5. The method of claim 1, wherein the offset is applied to the one of the timestamp associated with the event trace received from the CPU and the timestamp associated with the event trace received from the digital logic device by filtering the offset and adjusting one or more of a phase and a frequency of a clock of one of the CPU and the digital logic device.

6. The method of claim 5, wherein the one or more of the phase and the frequency of the clock of the one of the CPU and the digital logic device is adjusted by one of adjusting a phase-locked loop (PLL)/digital PLL (DPLL) that is synthesizing the clock and adjusting a time interval used to increment the clock.

7. The method of claim 1, wherein the offset is applied to the one of the timestamp associated with the event trace received from the CPU and the timestamp associated with the event trace received from the digital logic device via post-processing after the event trace is received from the CPU and the event trace is received from the digital logic device.

8. The method of claim 7, wherein the timestamp associated with the event trace received from the CPU is synchronized with the timestamp associated with the event trace received from the digital logic device by examining event trace files received from the CPU and event trace files received from the digital logic device and identifying common events that occurred on the CPU and the digital logic device, wherein common events occurring in one direction are identified to correct a frequency of the timestamps and common events occurring in both directions are identified to correct a clock associated with the timestamps, calculating delays of successive events that occur on one of the CPU and the digital logic device and then on another of the CPU and the digital logic device, filtering the calculated delays, calculating a time correction sequence, and applying the time correction sequence to the one of the timestamp associated with the event trace received from the CPU and the timestamp associated with the event trace received from the digital logic device as the offset.

9. The method of claim 8, wherein the time correction sequence is calculated using a digital phase-locked loop (DPLL) process by selecting a leader trace file and a follower trace file with an initial time correction sequence set to zero; using a frequency/phase detector to calculate a frequency/phase error between timestamps from the leader trace file and the follower trace file; if only correcting for frequency, calculating a difference between successive timestamps for the leader trace file and the follower trace file and then calculating a difference in time intervals for the leader trace file and the follower trace file; if correcting for phase,
for an event that is initiated in the leader trace file,
letting T1 be a timestamp of the event in the leader trace file, and
letting T2 be a timestamp of the event in the follower trace file,
for an event that is initiated on in the follower trace file,
letting T3 be a timestamp of the event in the follower trace file, and
letting T4 be a timestamp of the event in the leader trace file,
wherein a time error is calculated as error=(T1−T2−T3+T4)/2; and
applying the calculated error as the time correction sequence.

10. A non-transitory computer-readable medium comprising instructions stored in a memory and executed by a processor for carrying out steps of a method for analyzing event traces received from software and hardware, the method comprising
receiving an event trace from a central processing unit (CPU) running a software application,
receiving an event trace from a digital logic device associated with the CPU and software application, and
synchronizing a timestamp associated with the event trace received from the CPU with a timestamp associated with the event trace received from the digital logic device by applying a determined offset to one of the timestamp associated with the event trace received from the CPU and the timestamp associated with the event trace received from the digital logic device.

11. The non-transitory computer-readable medium of claim 10, wherein the offset is applied to the one of the timestamp associated with the event trace received from the CPU and the timestamp associated with the event trace received from the digital logic device inline in real-time as the event trace is received from the CPU and the event trace is received from the digital logic device or via post-processing after the event trace is received from the CPU and the event trace is received from the digital logic device.

12. A system for analyzing event traces received from software and hardware, the method comprising
a trace analyzer stored in memory and executed by a processor to
receive an event trace from a central processing unit (CPU) running a software application,
receive an event trace from a digital logic device associated with the CPU and software application, and
synchronize a timestamp associated with the event trace received from the CPU with a timestamp associated with the event trace received from the digital logic device by applying a determined offset to one of the timestamp associated with the event trace received from the CPU and the timestamp associated with the event trace received from the digital logic device.

13. The system of claim 12, wherein the digital logic device is one of a field-programmable gate array (FPGA), an application-specific integrated circuit (ASIC), and a programmable logic device (PLD).

14. The system of claim 12, wherein the offset is applied to the one of the timestamp associated with the event trace received from the CPU and the timestamp associated with the event trace received from the digital logic device inline in real-time as the event trace is received from the CPU and the event trace is received from the digital logic device.

15. The system of claim 12, wherein the offset is determined by, for a leader of the CPU and the digital logic device and a follower of the CPU and the digital logic device, generating by the leader a periodic event Xn and timestamping the event Xn as T1 in a trace of the leader, detecting the event Xn generated by the leader at the follower and timestamping the event Xn as T2 in a trace of the follower, generating by the follower a response event Yn and timestamping the event Yn as T3 in a trace of the follower, detecting the event Yn generated by the follower at the leader and timestamping the event Yn as T4 in a trace of the leader, and calculating the offset as: (T1−T2−T3+T4)/2.

16. The system of claim 12, wherein the offset is applied to the one of the timestamp associated with the event trace received from the CPU and the timestamp associated with the event trace received from the digital logic device by filtering the offset and adjusting one or more of a phase and a frequency of a clock of one of the CPU and the digital logic device.

17. The system of claim 16, wherein the one or more of the phase and the frequency of the clock of the one of the CPU and the digital logic device is adjusted by one of adjusting a phase-locked loop (PLL)/digital PLL (DPLL) that is synthesizing the clock and adjusting a time interval used to increment the clock.

18. The system of claim 12, wherein the offset is applied to the one of the timestamp associated with the event trace received from the CPU and the timestamp associated with the event trace received from the digital logic device via post-processing after the event trace is received from the CPU and the event trace is received from the digital logic device.

19. The system of claim 18, wherein the timestamp associated with the event trace received from the CPU is synchronized with the timestamp associated with the event trace received from the digital logic device by examining event trace files received from the CPU and event trace files received from the digital logic device and identifying common events that occurred on the CPU and the digital logic device, wherein common events occurring in one direction are identified to correct a frequency of the timestamps and common events occurring in both directions are identified to correct a clock associated with the timestamps, calculating delays of successive events that occur on one of the CPU and the digital logic device and then on another of the CPU and the digital logic device, filtering the calculated delays, calculating a time correction sequence, and applying the time correction sequence to the one of the timestamp associated with the event trace received from the CPU and the timestamp associated with the event trace received from the digital logic device as the offset.

20. The system of claim 19, wherein the time correction sequence is calculated using a digital phase-locked loop (DPLL) process by selecting a leader trace file and a follower trace file with an initial time correction sequence set to zero; using a frequency/phase detector to calculate a frequency/phase error between timestamps from the leader trace file and the follower trace file; if only correcting for frequency, calculating a difference between successive timestamps for the leader trace file and the follower trace file and then calculating a difference in time intervals for the leader trace file and the follower trace file; if correcting for phase,
for an event that is initiated in the leader trace file,
letting T1 be a timestamp of the event in the leader trace file, and
letting T2 be a timestamp of the event in the follower trace file,
for an event that is initiated on in the follower trace file,
letting T3 be a timestamp of the event in the follower trace file, and
letting T4 be a timestamp of the event in the leader trace file,
wherein a time error is calculated as error=(T1−T2−T3+T4)/2; and
applying the calculated error as the time correction sequence.
